(19) United States
(12) Patent Application Publication
(10) Pub. No.: US 2006/0134874 A1
(43) Pub. Date: Jun. 22, 2006

(54) Manufacture method of MOS semiconductor device having extension and pocket

(75) Inventor: Takayuki Kamiya, Iwata-shi (JP)

Correspondence Address: DICKSTEIN SHAPIRO MORIN & OSHINSKY LLP, 1177 AVENUE OF THE AMERICAS (6TH AVENUE), 41 ST FL., NEW YORK, NY, 10036-2714, US

(73) Assignee: YAMAHA CORPORATION

(21) Appl. No.: 11/304,587

(22) Filed: Dec. 16, 2005

(30) Foreign Application Priority Data
Dec. 17, 2004 (JP) 2004-365663

(51) Int. Cl. H01L 21/336; H01L 21/8242

(52) U.S. Cl. 438/305; 438/303; 438/239; 438/250

(57) ABSTRACT

A gate insulating film is formed on the surface of a semiconductor substrate in an opening of a field insulating film, and thereafter a gate electrode and a capacitor lower electrode made of doped polysilicon or the like are formed on the insulating film. Pocket regions are formed by an ion implantation process using the field insulating film and gate electrode as a mask, and thereafter an insulating layer is formed by CVD or the like covering the electrodes. Extension regions are formed by an ion implantation process via the insulating layer. An offset distance between the pocket region and the associated extension region can be determined at a high precision in accordance with a thickness of the insulating layer. After side spacers are formed, high concentration source/drain regions are formed.

### CROSS REFERENCE TO RELATED APPLICATION

This application is based on and claims priority of Japanese Patent Application No. 2004-365663 filed on Dec. 17, 2004, the entire contents of which are incorporated herein by reference.

### BACKGROUND OF THE INVENTION

A) Field of the Invention

The present invention relates to a manufacture method of a MOS semiconductor integrated circuit device having MOS transistors each being provided with extension regions for forming shallow junctions and pocket regions for suppressing short channel effects.

B) Description of the Related Art

A MOS transistor is known which has extension regions and pocket regions (refer, for example, to Patent Document 1 JP-A-HEI-8-162618, Non-Patent Document 1 “A study of tilt angle effect of Halo PMOS performance”, Microelectronics Reliability, Vol. 38 (1998), pp. 1503 to 1512, and Non-Patent Document 2 “High Performance Dual-Gate CMOS Utilizing a Novel Self-Aligned Pocket Implantation (SPT) Technology”, IEEE Transactions on Electron Devices, Vol. 40, No. 9, September 1993). FIGS. 13 to 16 illustrate a manufacture method of an n-channel MOS transistor analogous to a manufacture method of a p-channel MOS transistor described in Non-Patent Document 1.

In a process shown in FIG. 13, after a field oxide film 2 is formed on the surface of a p-type silicon substrate 1, a gate oxide film 3 is formed on the surface of a p-type silicon region in an element opening 2a of the oxide film 2. A gate electrode 4 of doped polysilicon or the like is formed on the gate oxide film 3. Thereafter, by using the field oxide film 2 and gate electrode 4 as a mask, boron ions B⁺ are implanted along oblique directions a plurality of times to form p-type pocket regions 5S and 5D in the p-type silicon region in the element opening on both sides of the gate electrode 4.

In the process shown in FIG. 14, by using the field oxide film 2 and gate electrode 4 as a mask, phosphorus ions P⁺ are implanted vertically to form n-type extension regions 6S and 6D in the p-type silicon region in the element opening 2a on both sides of the gate electrode 4. The p-type pocket region surrounds the n-type extension region.

In the process shown in FIG. 15, after a silicon oxide film is formed on the substrate by chemical vapor deposition (CVD), the silicon oxide film is etched back by anisotropic dry etching to form side spacers 7S and 7D on the side walls of the gate electrode 4.

In the process shown in FIG. 16, by using the field oxide film 2, gate electrode 4 and side spacers 7S and 7D as a mask, arsenic ions As⁺ are implanted to form high concentration source/drain regions 8S and 8D in the p-type silicon region in the element opening 2a on both sides of the gate electrode 4. The shallow extension regions protrude from the deep source/drain regions and the pocket regions surround the extension regions. Heat treatment is performed when necessary to activate implanted impurities.

Patent Document 1 indicates that if ion implantation for forming pocket regions is performed at a high energy, implanted ions pierce through the gate electrode layer and reach the channel region so that the threshold value is adversely affected, and proposes that an insulating layer having the same pattern as that of the gate electrode be formed on the gate electrode. After the source/drain regions are formed, pocket regions are formed through oblique ion implantation processes by using as a mask the field oxide film, a lamination of the gate electrode and insulating layer, and side spacers.

In the manufacture method of MOS transistors described in Non-Patent Document 2, pocket regions are formed after deep and high concentration source/drain regions are formed. Namely, the gate oxide film on the source/drain regions is selectively removed to expose the surfaces of the source/drain regions. After silicide layers are formed on the upper surfaces of the gate electrode and source/drain regions by a well-known salicide process, the side spacers are removed. Thereafter, pocket regions are formed by oblique ion implantation processes.

The transistor structure having pocket regions and extension regions are frequently used for transistors of the so-called sub-micron generation to quarter micron generation, to form shallow junctions by the extension regions and suppress the short channel effects by the pocket regions.

Pocket regions are formed by oblique ion implantation processes. Extension regions are formed by vertical ion implantation. A masking function of the upper edges of the gate electrode becomes dominant in vertical ion implantation, whereas a masking function of the lower edges of the gate electrode becomes dominant in the oblique ion implantation processes. If the lower portion of the gate electrode layer is worked thin or the side walls of the gate electrode are worked obliquely, because of the influences of the factors that the edges of the pocket regions and extension regions are dominated by different factors, the offset distance L between the pocket region and extension region may change from the design value. Therefore, the effect of the pocket regions suppressing extension of depleted layers extending from the extension regions is changed, resulting in a variation in a transistor threshold voltage and in an on-state drive current.

### SUMMARY OF THE INVENTION

An object of this invention is to provide a novel manufacture method of a semiconductor device having MOS transistors each being provided with pocket regions and extension regions.

Another object of this invention is to provide a novel manufacture method of a semiconductor device having capacitors and MOS transistors each being provided with pocket regions and extension regions.

Still another object of this invention is to provide a manufacture method of a semiconductor device capable of improving a precision of an offset distance between a pocket region and an associated extension region of a MOS transistor.

According to one aspect of the present invention, there is provided a semiconductor device manufacture method comprising the steps of: (a) forming an isolation region in a semiconductor substrate, the isolation region defining an active region of a first conductivity type; (b) forming a gate insulating film on a surface of the active region; (c) forming a gate electrode on the gate insulating film; (d) implanting impurity ions of the first conductivity type in the active region by using the gate electrode as a mask, to form pocket regions; (e) after the step (d), depositing a first insulating film on the semiconductor substrate, the first insulating film covering side surfaces and an upper surface of the gate electrode; (f) implanting impurity ions of a second conductivity type opposite to the first conductivity type in the active region by using the gate electrode and the first insulating film as a mask, to form extension regions; (g) forming side spacers on side walls of the first insulating film; and (h) implanting impurities of the second conductivity type into the active region by using the gate electrode, the first insulating film, and the side spacers as a mask, to form source/drain regions.

Pocket regions are formed by ion implantation before the insulating film is formed on the side walls of a gate electrode, and extension regions are formed by ion implantation after the insulating film is formed on the side walls of the gate electrode. Thus, the precision of the relative position of these two can be easily controlled.

### BRIEF DESCRIPTION OF THE DRAWINGS

FIG. 1 is a cross sectional view illustrating a process of forming a gate electrode in a manufacture method for a MOS semiconductor integrated circuit device according to an embodiment of the present invention.

FIG. 2 is a cross sectional view illustrating an ion implantation process of forming pocket regions following the process shown in FIG. 1.

FIG. 3 is a cross sectional view illustrating an insulating layer forming process following the process shown in FIG. 2.

FIG. 4 is a cross sectional view illustrating an ion implantation process of forming extension regions following the process shown in FIG. 3.

FIG. 5 is a cross sectional view illustrating a conductive material layer forming process following the process shown in FIG. 4.

FIG. 6 is a cross sectional view illustrating a resist layer forming process following the process shown in FIG. 5.

FIG. 7 is a cross sectional view illustrating a selective etching process and a resist removing process following the process shown in FIG. 6.

FIG. 8 is a cross sectional view illustrating an insulating material layer forming process following the process shown in FIG. 7.

FIG. 9 is a cross sectional view illustrating an anisotropic etching process following the process shown in FIG. 8.

FIG. 10 is a cross sectional view illustrating an ion implantation process of forming high concentration source/drain regions following the process shown in FIG. 9.

FIG. 11 is a cross sectional view illustrating an anisotropic etching process and a resist removing process in a MOS semiconductor integrated circuit device manufacture method according to a modification of the embodiment.

FIG. 12 is a cross sectional view illustrating an ion implantation process of forming high concentration source/drain regions following the process shown in FIG. 11.

FIG. 13 is a cross sectional view illustrating an oblique ion implantation process of forming pocket regions in a conventional MOS semiconductor integrated circuit device manufacture method.

FIG. 14 is a cross sectional view illustrating an ion implantation process of forming

extension regions following the process shown in FIG. 13.

FIG. 15 is a cross sectional view illustrating a side spacer forming process following the process shown in FIG. 14.

FIG. 16 is a cross sectional view illustrating an ion implantation process of forming high concentration source/drain regions following the process shown in FIG. 15.

### DESCRIPTION OF THE PREFERRED EMBODIMENTS

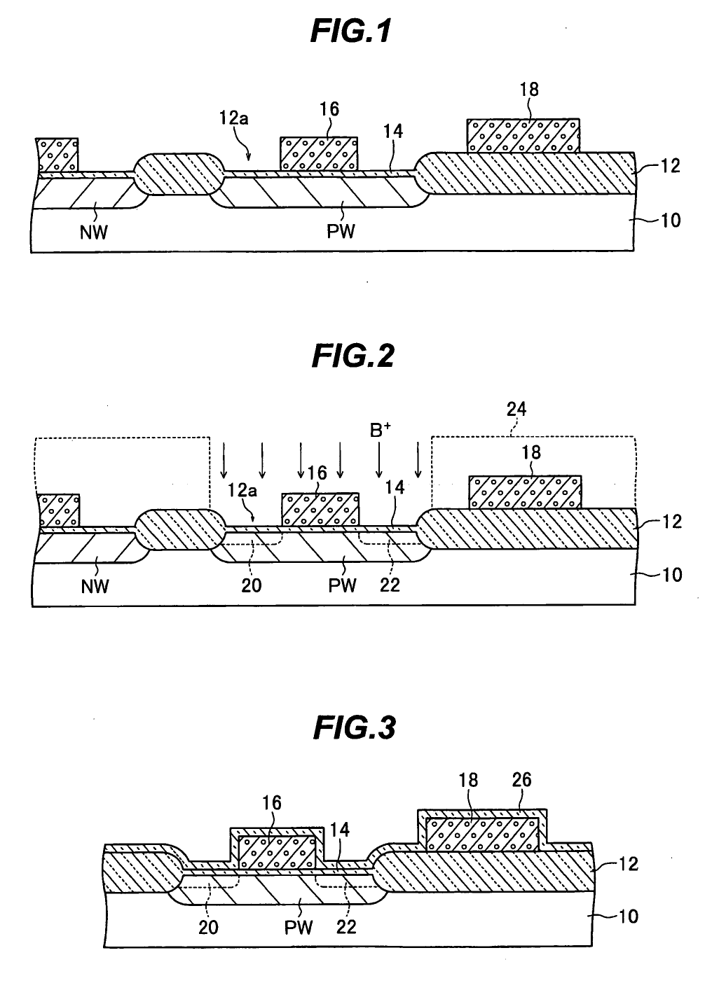

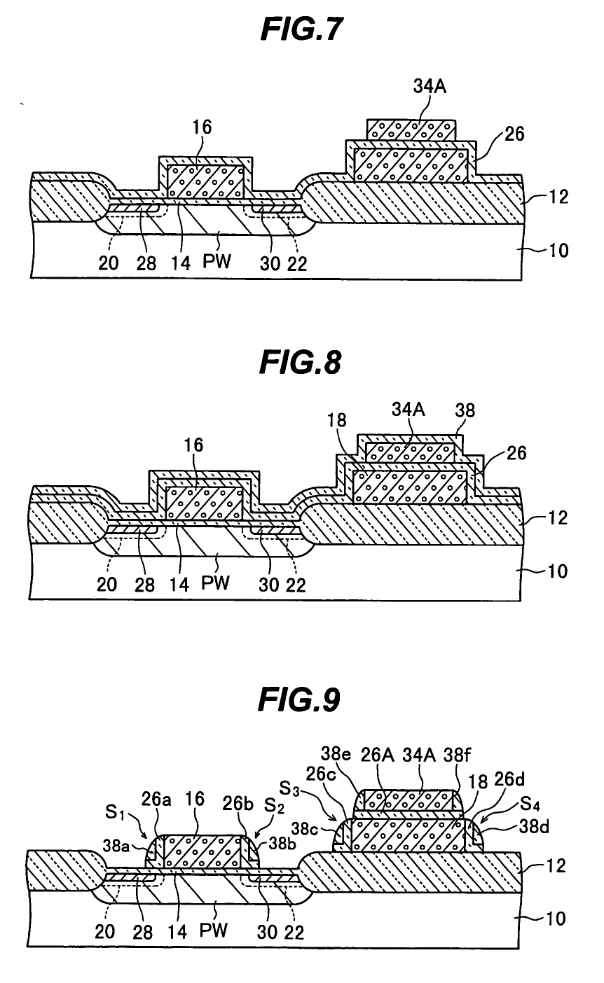

FIGS. 1 to 10 illustrate a manufacture method of a MOS semiconductor integrated circuit (IC) device according to the embodiment of the present invention. Processes (1) to (10) corresponding to FIGS. 1 to 10 will be described sequentially. In an example shown in FIGS. 1 to 10, a MOS IC device is formed which has n-channel MOS transistors and capacitors.

(1) A field insulating (oxide) film 12 of silicon oxide is formed by a well-known local oxidation of silicon (LOCOS) method on one principal surface of a semiconductor substrate 10 made of, for example, silicon. The semiconductor substrate 10 has a p-type well PW and an n-type well NW in the principal surface layer. The substrate 10 may either be a p-type or an n-type. The field insulating film 12 may be formed by shallow trench isolation (STI) which deposits a silicon oxide film in a trench formed in the principal surface layer of the substrate 10 and removes an unnecessary portion by chemical mechanical polishing (CMP) or the like. A gate insulating film 14 of silicon oxide having a thickness of 14 nm is formed on the surface of the p-type semiconductor region in an element opening 12a surrounded by the insulating film 12, by well-known thermal oxidation.

An electrode material layer having a thickness of 300 nm is formed on the substrate, covering the field insulating film 12 and gate insulating film 14. This electrode material layer is patterned by photolithography and dry etching, to form a gate electrode 16 having a gate length of 0.65 μm and a first electrode 18 of a capacitor, respectively on the gate insulating film 14 and field insulating film 12. The electrode material layer may be a doped polysilicon layer or a polycide layer (a lamination of a polysilicon layer and a silicide layer of refractory metal such as Ti, W and Mo deposited on the polysilicon layer). The first electrode 18 is used as a capacitor lower electrode. Resistors or the like may also be formed.

(2) First and second p-type pocket regions 20 and 22 are formed in the p-type semiconductor region in the element opening 12a on both sides of the gate electrode 16, by impurity ion implantation using as a mask the field insulating film 12 and gate electrode 16. For example, the impurity ion implantation may be performed by implanting boron ions B⁺ under the conditions of an acceleration energy of 40 keV, a dose of 4.0×10¹²cm⁻² and vertical implantation along the normal to the substrate. In this case, ion implantation may be slightly inclined if desired, instead of a right angle relative to the principal surface of the substrate 10.

The pocket regions 20 and 22 are formed by ion implantation using the gate electrode as a mask to define the edge of the pocket region in the lateral direction by the edge of the gate electrode.

In forming a complementary MOS (CMOS) IC device, an impurity implantation process is executed by disposing on the substrate a resist layer 24 as an impurity mask exposing an element opening 12a and covering the p-channel MOS (PMOS) transistor region. The resist layer 24 is thereafter removed. By using a resist mask covering the NMOS region and capacitor, ion implantation is performed for the PMOS region. Mainly, the NMOS region will be described in the following.

(3) A conformal insulating layer 26 is formed on the field insulating film 12 and gate insulating film 14, covering the gate electrode 16 and first electrode 18. The conformal insulating film 26 is formed on the side walls of the gate electrode 16 at a uniform thickness and forms new side walls on the side walls of the gate electrode spaced by a predetermined distance from the gate electrode side walls. The conformal insulating film 26 is also formed on the first electrode 18 and used as a capacitor insulating film. For example, a silicon oxide film (SiO₂ film) having a thickness of 70 nm may be formed by CVD. Other examples of the insulating film 26 may be a silicon nitride film (SiN film), a silicon oxynitride film (SiON film) or a high dielectric constant film (e.g., a tantalum oxide film [TaₓO_{y}: e.g., x=2, y=5]), or laminations of these films (e.g., SiO₂/SiN, SiO₂/SiN/SiON, SiO₂/TaₓO_{y}/SiO₂, SiON/TaₓO_{y}/SiON, etc.). An expression of a lamination such as A/B means that a lamination having A stacked on B.

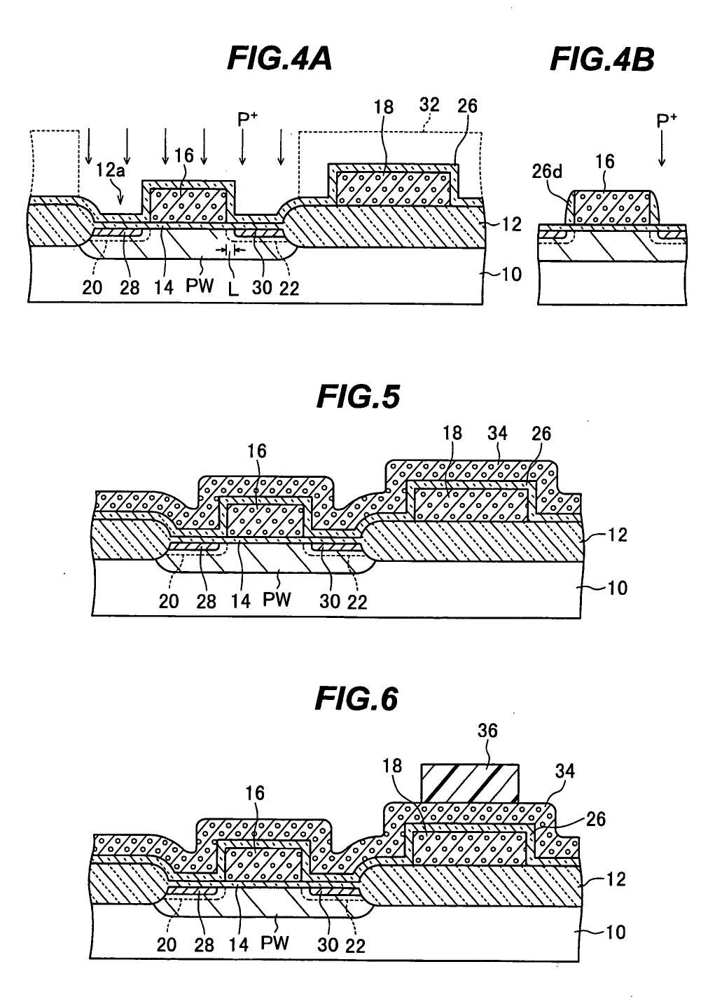

(4) An n-type impurity ion implantation process using as a mask a lamination of the field insulating film 12 and insulating layer 26 and a lamination of the gate electrode 16 and insulating layer 26, n-type extension regions 28 and 30 are formed in the p-type semiconductor region in the element opening 12a on both sides of the gate electrode 16, as shown in FIG. 4A. Since the insulating film 26 is deposited on the side walls of the gate electrode 16, the inner edges (on the gate electrode side) of the extension regions 28 and 30 are offset from the edges of the pocket regions outward by the thickness of the insulating film. For example, the impurity ion implantation may be performed by implanting phosphorus ions P⁺ under the conditions of an acceleration energy of 80-120 keV, more preferably 100 keV, a dose of 2×10¹³cm⁻² and vertical implantation. In this case, since the insulating layer 26 functions as an impurity mask on both sides of the gate electrode 16, an offset distance L between the pocket regions 20 and 22 and extension regions 28 and 30 can be determined at a high precision in accordance with the thickness of the insulating layer 26.

Before the P⁺ ion implantation, the insulating layer 26 may be anisotropically etched by reactive ion etching to leave side wall spacers 26a on side walls of the gate electrode 16 as shown in FIG. 4B. Then, P⁺ ion implantation for forming extensions will be effected with an acceleration energy of 50 keV.

In forming a CMOS IC device, an ion implantation process is performed by disposing on the substrate a resist layer 32 as an impurity mask exposing the element opening 12a and covering a p-channel MOS transistor region. The resist layer 32 is thereafter removed, a mask exposing the PMOS region is formed and p-type impurities are implanted.

(5) A conductive material layer 34 is formed on the substrate, covering the insulating layer 26. For example, the conductive material layer 34 is formed by depositing a polysilicon layer having a thickness of 150 nm by CVD and doping phosphorus at a concentration of 1×10²⁰cm⁻³ or higher during depositing the polysilicon layer to reduce its resistance.

(6) A resist layer 36 is formed on the conductive material layer 34 by photolithography, the resist layer having a pattern of an upper electrode of the capacitor.

(7) The conductive layer 34 is subjected to a dry etching process using the resist layer 36 as a mask to form a second capacitor electrode 34A made of the left portion of the conductive material layer 34. The resist layer 36 is thereafter removed. The second electrode 34A is used as the capacitor upper electrode. (8) An insulating material layer 38 is formed on the insulating layer 26, covering the second electrode 34A. The insulating material layer 38 together with the insulating layer 26 is used as a side spacer. For example, a silicon oxide film having a thickness of 150 nm may be formed by CVD.

(9) A lamination of the insulating layer 26 and insulating material layer 38 is etched back by anisotropic dry etching to form side spacers S₁ and S₂ on both side surfaces of the gate electrode 16. The side spacer S₁ is made of a left portion 26a of the insulating layer 26 and a left portion 38a of the insulating material layer 38, and the side spacer S₂ is made of a left portion 26b of the insulating layer 26 and a left portion 38b of the insulating material layer 38.

In this anisotropic dry etching process, side spacers S₃ and S₄ are also formed on both side surfaces of the first electrode 18. The side spacer S₃ is made of a left portion 26c of the insulating layer 26 and a left portion 38c of the insulating material layer 38, and the side spacer S₄ is made of a left portion 26d of the insulating layer 26 and a left portion 38d of the insulating material layer 38. A portion of the insulating layer 26 is left as a capacitor insulating film 26A between the first and second electrodes 18 and 34A, and side spacers 38e and 38f made of left portions of the insulating layer 38 are formed on side surfaces of the second electrode 34. The first and second electrodes 18 and 34A and the insulating film 26A constitute a parallel plate type capacitor.

In the anisotropic etching process shown in FIG. 9, the gate insulating film 14 may be removed selectively between the field oxide film 12 and side spacers S₁ and S₂ to partially expose the surfaces of the extension regions 28 and 30.

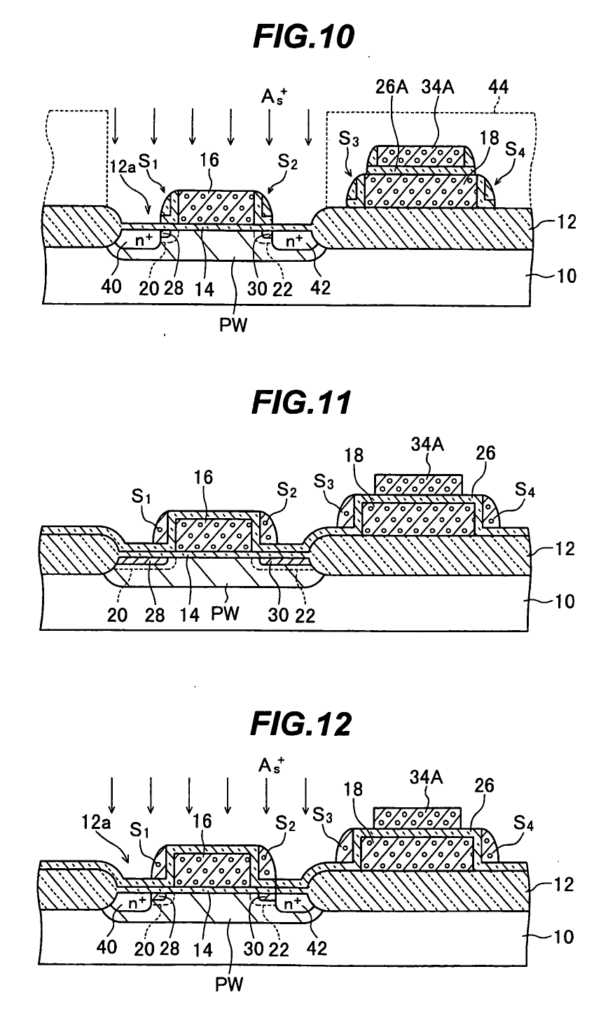

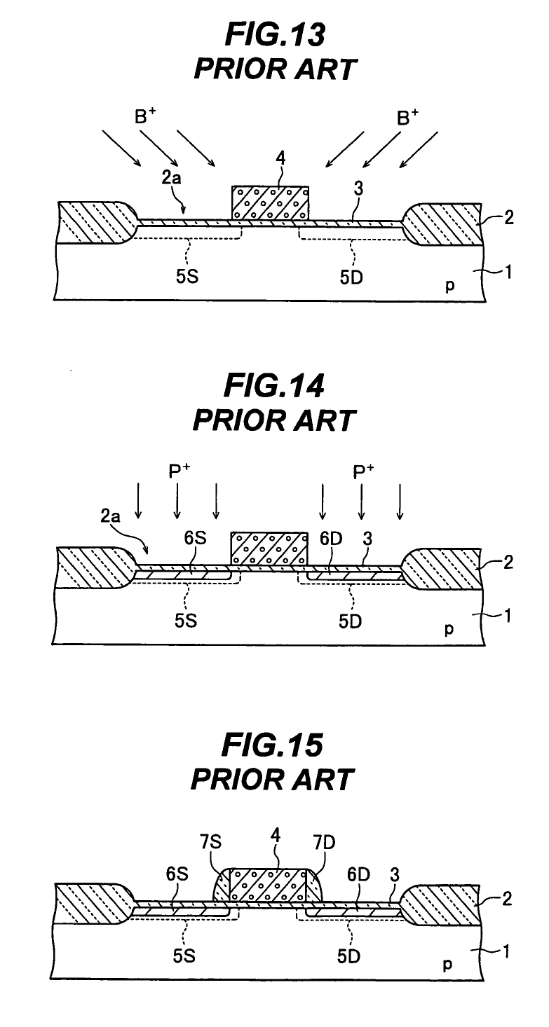

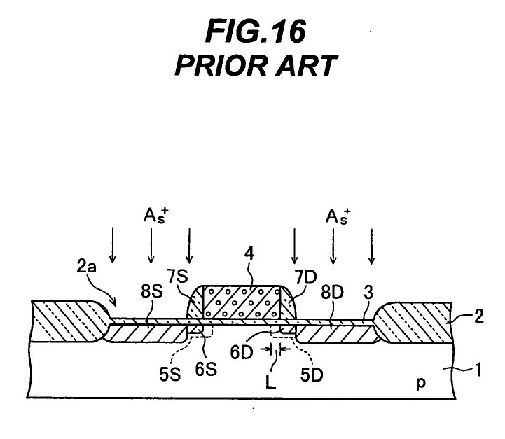

(10) By an impurity ion vertical implantation process using as a mask the field insulating film 12, gate electrode 16 and side spacers S₁ and S₂, n-type high concentration source/drain regions 40 and 42 are formed in the p-type semiconductor region in the element opening 12a on both sides of the gate electrode 16. Since the ion implantation for the source/drain regions 40 and 42 uses also the side spacers as a mask, the inner edges of the source/drain regions are offset from the inner edges of the extension regions 28 and 30 by a thickness of the insulating material layer 38. In FIG. 10, “n⁺” indicates a high impurity concentration n-type. For example, in the impurity ion implantation process, arsenic ions As⁺ may be implanted under the conditions of an acceleration energy of 70 keV and a dose of 5.0×10¹⁵cm⁻², if necessary, by vertical implantation via the mask 44. In this case, the edges of the source/drain regions 40 and 42 on the side of the gate electrode 16 are determined at a high precision in accordance with the thicknesses of the side spacers S₁ and S₂ along the source-drain direction.

Although ion implantation along a vertical direction relative to the substrate surface has been described mainly, ion implantation may be performed by inclining the implantation direction by a predetermined angle. Also in this case, an offset between the pocket region and extension region is determined in accordance with the thickness of the insulating film 26 and an offset between the extension region and source/drain region is determined in accordance with a thickness of the side spacer.

In forming a CMOS IC device, by using resist masks in the manner similar to that described above, n- and p-type impurities are implanted separately.

After the impurity ion implantation process shown in FIG. 10, heat treatment is performed to activate implanted impurities. For example, this heat treatment may be performed for 40 minutes at 950° C. After the implanted impurity activation heat treatment and other heat treatment, the pocket regions 20 and 22, extension regions 28 and 30 and high concentration source/drain regions 40 and 42 all have final boundaries at extended positions due to impurity diffusion. For example, in the case of the extension regions 28 and 30, an impurity distribution during ion implantation has a lateral extension of about 20 nm. The heat treatment for 40 minutes at 950° C. includes a temperature raising process and a temperature lowering process and is accompanied by a diffusion length of about 60 nm. By adding both extensions, the extension regions 28 and 30 extend toward the gate electrode side by about 80 nm from the outer side surface of the insulating film 26. As a result, the extension regions 28 and 30 overlap the gate electrode 16. In order not to make the channel under the gate electrode 16 be spaced from the extension region 30 in an on-state of the MOS transistor, it is preferable that the heat treatment conditions are selected so that the edge of the extension region 30 on the gate side is positioned under the gate electrode 16.

In the embodiment described above, as shown in FIG. 4, the offset distances between the pocket regions 20 and 22 and extension regions 28 and 30 can be determined at a high precision in accordance with the thickness of the insulating layer 26. Further, as shown in FIG. 10, the positions of the high concentration source/drain regions 40 and 42 relative to the extension regions 28 and 30 can be determined at a high precision in accordance with the thickness of the insulating material layer 38 in a source-drain direction. Accordingly, a variation in transistor characteristics such as a threshold voltage and on-state drive current can be reduced and a manufacture yield can be improved. The first electrode 18 of the capacitor is formed by utilizing the process of forming the gate electrode 16, and the insulating layer 26 for setting the offset distance L is utilized as the capacitor insulating film 26A. Therefore, a MOS IC device having a MOS transistor and a capacitor can be manufactured by a small number of processes, and the cost reduction can be realized.

Although vertical ion implantation has been described mainly, ion implantation may be inclined by a predetermined angle. This angle may be changed with each ion implantation. For example, only ion implantation for pocket regions may be inclined. A thickness of the insulating film 26 may be adjusted in accordance with an inclination angle. Also in these cases, it can be said that the offset distance is determined in accordance with a thickness of the insulating film.

FIGS. 11 and 12 illustrate a manufacture method of a MOS IC device according to a modification of the above-described embodiment. Similar elements to those shown in FIGS. 1 to 10 are represented by using similar reference numerals, and the detailed description thereof is omitted. The process shown in FIG. 11 corresponds to the anisotropic etching process following the process shown in FIG. 6.

In the process shown in FIG. 11, the conductive material layer 34 is etched back by anisotropic etching to form side spacers S₁ and S₂ made of left portions of the conductive material layer 34, on side surfaces of the gate electrode 16 with the insulating layer 26 being interposed. In this case, side spacers S₃ and S₄ made of left portions of the conductive material layer 34 are also formed on side surfaces of the capacitor first electrode 18, with the insulating layer 26 being interposed. Since the conductive material layer 34 is etched by using the resist layer 36 as a mask, the capacitor second electrode 34A made of a left portion of the conductive material layer 34 corresponding in shape to the resist layer 36 is formed above the first electrode 18.

Not only the capacitor upper electrode but also side spacers are formed by the conductive material layer 34. Although the width of the side spacer is restricted by the thickness of the capacitor upper electrode, it is not necessary to form another insulating film for side spacers and etch the insulating film.

In the process shown in FIG. 12, n-type high concentration source/drain regions 40 and 42 are formed in a manner similar to that described with FIG. 10, by using as a mask the field insulating film 12, gate electrode 16 covered with the insulating layer 26 and first and second side spacers S₁ and S₂ stacked on the insulating layer 26.

In the modification described above with FIGS. 11 and 12, operations and effects similar to those of the embodiment described with FIGS. 1 to 10 can be obtained, and the capacitor forming process can be made simpler because the MOS transistor forming process is utilized for the second electrode 34A.

In the modification described above, although the capacitor upper electrode is formed by utilizing the process of forming the side spacers S₁ and S₂, electrodes of circuits other than the capacitor may also be formed. Further, the side spacers S₁ and S₂ may be formed by using the conductive material layer 34 instead of the insulating material layer 38 shown in FIG. 8.

As above, the offset distances between the pocket regions and extension regions can be determined at a high precision in accordance with the thickness of the side spacer material. Therefore, a variation in transistor characteristics such as a threshold voltage and on-state drive current can be reduced and a manufacture yield can be improved.

Since the capacitor is formed by utilizing the process of forming the MOS transistor, semiconductor devices such as a MS IC device having a MOS transistor and a capacitor can be manufactured by a small number of processes and cost reduction can be realized.

The present invention has been described in connection with the preferred embodiments. The invention is not limited only to the above embodiments. It will be apparent to those skilled in the art that other various modifications, improvements, combinations, and the like can be made.

What are claimed are:

1. A semiconductor device manufacture method comprising the steps of:
(a) forming an isolation region in a semiconductor substrate, said isolation region defining an active region of a first conductivity type;
(b) forming a gate insulating film on a surface of said active region;
(c) forming a gate electrode on said gate insulating film;
(d) implanting impurity ions of the first conductivity type in said active region by using said gate electrode as a mask, to form pocket regions;
(e) after said step (d), depositing a first insulating film on said semiconductor substrate, said first insulating film covering side surfaces and an upper surface of said gate electrode;
(f) implanting impurity ions of a second conductivity type opposite to the first conductivity type in said active region by using said gate electrode and said first insulating film as a mask, to form extension regions;
(g) forming side spacers on side walls of said first insulating film; and
(h) implanting impurities of the second conductivity type into said active region by using said gate electrode, said fist insulating film, and said side spacers as a mask, to form source/drain regions.

2. The semiconductor device manufacture method according to claim 1, wherein said step (e) forms said first insulating film conformal to an underlying structure.

3. The semiconductor device manufacture method according to claim 1, wherein the ion implantation in said steps (d) and (f) are performed vertically relative to a surface of said semiconductor substrate.

4. The semiconductor device manufacture method according to claim 1, further comprising the step of:
(i) executing heat treatment to make said extension regions diffuse and reach under said gate electrode.

5. The semiconductor device manufacture method according to claim 1, wherein said step (g) comprises the steps of:
(g-1) forming a side spacer film material film on said first insulating film; and
(g-2) etching said side spacer material film and said first insulating film to leave side spacers on the side walls of said gate electrode.

6. The semiconductor device manufacture method according to claim 5, wherein the side spacer material film is a second insulating film.

7. The semiconductor device manufacture method according to claim 6, wherein said step (c) also forms a capacitor lower electrode on said isolation region, said step (e) also forms said first insulating film on said capacitor lower electrode, and the semiconductor device manufacture method further comprises a step of:
(j) forming a capacitor upper electrode on said first insulating film and above said capacitor lower electrode, between said steps (f) and (g).

8. The semiconductor device manufacture method according to claim 5, wherein said side spacer material film is a conductive film.

9. The semiconductor device manufacture method according to claim 8, wherein said step (c) also forms a capacitor lower electrode on said element isolation region, said step (e) also forms said first insulating film on said capacitor lower electrode, and said step (g-2) forms a capacitor upper electrode on said first insulating film and above said capacitor lower electrode.

10. The semiconductor device manufacture method according to claim 9, wherein said step (g-2) is an etch-back process using a resist mask having a shape of said capacitor upper electrode.
